(19) United States
(12) Patent Application Publication
(10) Pub. No.: US 2026/0318761 A1
(43) Pub. Date: Oct. 15, 2026

(54) METHOD FOR CALIBRATING A MODEL FOR ESTIMATING A TORQUE SUPPLIED BY AN ELECTRIC MACHINE

(71) Applicant: SAFRAN HELICOPTER ENGINES, BORDES (FR)

(72) Inventors: David Bernard Martin LEMAY, MOISSY-CRAMAYEL (FR); Jean-Luc Charles Gilbert FREALLE, MOISSY-CRAMAYEL (FR); Thomad KLONOWSKI, MOISSY-CRAMAYEL (FR)

(73) Assignee: SAFRAN HELICOPTER ENGINES, BORDES (FR)

(21) Appl. No.: 19/111,040

(22) PCT Filed: Sep. 12, 2023
(86) PCT No.: PCT/FR2023/051386

§ 371 Date: Mar. 12, 2025

(30) Foreign Application Priority Data
Sep. 16, 2022 (FR) FR2209360

(51) Int. Cl. G01L 5/13; G01L 25/00; G01R 19/165; G01R 31/34

(52) U.S. Cl. CPC G01L 5/13; G01L 25/003; G01R 19/16528; G01R 19/16533; G01R 31/343

(57) ABSTRACT

A method for calibrating a model for estimating a torque provided by an electric machine includes measuring an electric current through the electric machine for an operating point of the electric machine, estimating the torque provided by the electric machine for said operating point of the electric machine, based on the electric current measured and based on an estimation model associating an output torque with an input electric current, measuring a reference torque provided by the electric machine for the operating point of the electric machine, comparing the estimated torque with the reference torque, and as a function of the comparison, adjusting the estimation model so as to reduce, or cancel out, a difference between the estimated torque and the reference torque.

### TECHNICAL FIELD

This application relates to a method for calibrating a model for estimating a torque provided by an electric machine. The application also relates to a calibrating device for estimating a torque provided by an electric machine.

### TECHNICAL BACKGROUND

A machine, thermal or electrical, can be a motor or a generator, and is conventionally used in industry to provide power to a system. In particular, electric machines are used at the present time to provide propulsive power to an aircraft propulsion unit such as a helicopter rotor, a propeller, or a turbojet engine fan. The machine supplies mechanical power in the form of torque and speed over a rotation shaft. The machine is controlled by an electronic control system with the aim of tracking a speed or torque setpoint meeting the requirements of the system.

The control of the torque provided by the machine in operation is important to the proper operation of the system. In particular, when an electric machine is used for aeronautical propulsion, the control of the torque is a flight safety issue. Specifically, the application of an erroneous torque can have critical consequences for flight safety. The application of an excessively high torque may lead to an exceeding of the maximum torque for which the mechanical transmission system was designed and thus generate damage which can lead to the failure of a critical part such as a main gear box of a helicopter, or a propeller. The application of excessively low torque, i.e. a torque less than the maximum torque that the propulsion system should be able to provide, can lead to a lack of propulsive power which can be critical in certain flight phases.

An uncertainty about the torque information provided by the machine is taken into account in the design of the machine and its control system, to guarantee flight safety. However, a significant uncertainty incurs either an overdimensioning of the mechanical transmission and therefore an increase in the empty weight of the aircraft, or a reduction in the performance of the aircraft (payload capacity, range, etc.), which lessens its economic viability.

The torque information provided by a thermal or electric machine can be obtained by direct measurement using a torque sensor, also known as a torquemeter disposed for example on the engine shaft of the thermal machine or at another place on the mechanical transmission system. Such a sensor generally measures the deformation of a mechanical part subjected to the torque provided by the machine. The measurement obtained is accurate. On the other hand, it requires dedicated electronics, with the associated fault management and reliability problems. A procedure of calibration of the sensor is generally needed to obtain the desired accuracy, and finally, a torque sensor is a heavy, cumbersome and expensive device, and this therefore has a negative impact on the design of the system.

In the case of electric machines, the electronic control system of these machines is based on an electric current measurement traversing the machine, by a current sensor. It is then possible to estimate the torque provided by the electric machine by the following relationship: T=Kt*I, where T is the torque, I is the electric current through the machine, and Kt is a characteristic torque constant of the machine under consideration. This estimating method, by indirect torque measurement, is simple and inexpensive in terms of integration (cost, mass, reliability) since it is based on a current sensor for which provision is made by design. But such an estimation of the torque lacks accuracy. For an electric machine for which provision is made in an aeronautical propulsion system, this lack of accuracy on the estimated torque value poses a problem for flights safety.

The factors of inaccuracy on the indirect measurement of the torque provided by the electric machine by way of an electric current measurement are mainly:
the measurement of the electric current itself, which generally has an accuracy in the order of +/−5 to 10% of the full measurement scale,
the torque constant Kt of the electric machine, which is a characteristic associated with a given machine topology, but which can vary according to the manufacturing and assembly tolerances, the order of magnitude of the dispersion on the value Kt being also of +/−5 to 10% of the “average” nominal value, and
various other sources of inaccuracy, in particular those related to the control electronics of the electric machine, to the operating conditions of use and particularly the temperature, or to the supply voltage, or else ageing, etc.

### GENERAL SUMMARY

One aim of this application is to make provision for a method for calibrating a model for estimating a torque provided by an electric machine and a corresponding calibrating device, making it possible to improve the accuracy of a torque estimate based on a measurement of electric current through the electric machine, which makes it possible to dispense with the need to incorporate a specific torque measurement sensor with problems of integration (cost, mass, weight) and reliability, and which is simple to implement.

According to a first aspect, this application relates to a method for calibrating a model for estimating a torque provided by an electric machine, particularly by a permanent-magnet motor, comprising the following steps:
E1 measuring an electric current through the electric machine for an operating point of the electric machine;
E2 estimating the torque provided by the electric machine for said operating point of the electric machine, based on the electric current measured and on the estimation model associating an output torque with an input electric current;
E3 measuring a reference torque provided by the electric machine for said operating point of the electric machine;
E4 comparing the estimated torque with the reference torque; and
E5 as a function of said comparison, adjusting the estimation model so as to reduce, or even cancel out, a difference between the estimated torque and the reference torque.

Certain preferred but non-limiting features of the calibrating method according to the first aspect are as follows, taken individually or in combination:
the method further comprises a step E6 of storing the adjusted estimation model in a memory of a control system;
the steps E1 to E4 are repeated for several different operating points of the electric machine;
the estimation model comprises an affine function, and wherein the adjustment of the estimation model comprises an adjustment of a gradient and/or of a y-intercept of the affine function;
the estimation model comprises a lookup table associating with each of a plurality of electric input currents a corresponding output torque, and wherein the estimating of the torque in the step E2 comprises a recalibration of at least one output torque value of the lookup table during the step E5 as a function of the comparison between the estimated torque and the reference torque made in the step E4, such as to reduce or even cancel out the difference between the estimated torque and the reference torque;
the estimation model comprises a set of lookup tables, each lookup table being associated with a temperature from among a set of operating temperatures of the electric machine, and wherein the estimating of the torque in the step E2 comprises a sub-step of selecting a lookup table associated with a temperature of the electric machine at the operating point;
the estimation model is adjusted so as to reduce, or even cancel out, a difference between the estimated torque and the reference torque, over a given electric current range [Ik, In], and/or for a given operating temperature range; and/or
the method comprises: a step of calibrating the electric machine, comprising a sub-step of measuring the no-load electromotive force of the electric machine and a sub-step of measuring a rotation speed of the electric machine, for an operating point of the electric machine, and a sub-step of determining an electric machine model associating with the electromotive force a rotation speed of the electric machine, based on the measured electromotive force and the measured rotation speed; a step of calibrating the control system, comprising a sub-step of measuring an electric current through the control system on a static load test bench equipped with a master current sensor to obtain a reference current measurement, a sub-step of computing a measurement error on the quadratic current of the control system with respect to the measurement of the reference current, and a sub-step of creating a shaping model in order to correct the current measurement commanded by the control system based on the reference current measurement; and a step of storing the electric machine model and the shaping model of the control system in the control unit.

According to a second aspect, this application makes provision for a calibrating device for estimating a torque provided by an electric machine, particularly by a permanent-magnet motor, comprising:
a device for measuring an electric current suitable for measuring the electric current through the electric machine for an operating point of the electric machine;
an estimation model associating an output torque with an input electric current, such that the estimation model is suitable for estimating a torque provided by the electric machine for said operating point of the electric machine, based on the measured electric current;
a torquemeter suitable for measuring a reference torque provided by the electric machine for said operating point of the electric machine; and
a control unit suitable for comparing the estimated torque with the reference torque, the control unit being moreover suitable for adjusting the estimation model as a function of said comparison, so as to reduce, or even cancel out, a difference between the estimated torque and the reference torque.

Optionally, the calibrating device according to the second aspect further comprises:
a first chamber suitable for replicating first external conditions, the first chamber being suitable for receiving the electric machine during the calibration; and
a second chamber suitable for replicating second external conditions, the second chamber being suitable for receiving the control system of the electric machine during the calibration.

### DESCRIPTION OF THE FIGURES

Other features, aims and advantages of this application will become apparent on reading the following detailed description, given by way of non-limiting example, which will be illustrated by the following figures:

FIG. 1 is a diagram illustrating a calibrating device for estimating a torque provided by an electric machine according to an embodiment.

FIGS. 2a and 2b are graphs illustrating a calibration of a model for estimating the torque provided by an electric machine obtained in a calibrating method according to an embodiment.

FIG. 3 is a diagram illustrating a calibrating method for estimating a torque provided by an electric machine according to an embodiment.

FIG. 4 is a diagram illustrating a step of estimating a torque provided by an electric machine in the context of a calibrating method according to an embodiment.

FIG. 5 is a diagram illustrating a step of calibrating an electric machine, a step of calibrating a control system, and a step of storing an estimation model in a control unit, in the context of a calibrating method according to an embodiment.

### DETAILED DESCRIPTION

A calibrating method, also known as a shaping method, of a model for estimating a torque provided by an electric machine 10, particularly by a permanent-magnet motor, is illustrated by way of non-limiting example FIG. 3. The calibrating method comprises the following steps:
E1: measuring an electric current through the electric machine 10 for an operating point of the electric machine 10;
E2: estimating the torque provided by the electric machine 10 for said operating point of the electric machine 10, based on the measured electric current and on an estimation model associating an output torque with an input electric current;
E3: measuring a reference torque provided by the electric machine 10 for said operating point of the electric machine 10;
E4: comparing the estimated torque with the reference torque; and
E5: as a function of said comparison, adjusting the estimation model such as to reduce, or even cancel out, a difference between the estimated torque and the reference torque.

The estimation model can for example be intended to be used in flight during the operation of an electric machine 10 intended to provide a torque to a propulsion system of an aircraft.

The estimating of the torque is thus done by indirect measurement, based on the measurement of the electric current through the electric machine 10. Consequently, one benefits from an accurate estimate of the torque, which makes it possible to avoid the use of a specific torque measurement sensor, which uses a sensor 30 for measuring the electric current through the electric machine 10 naturally present.

The calibration of the torque estimation model is thus performed on a full system in particular comprising a device for measuring the electric current 30, a control system 20 of the electric machine 10 as well as the electric machine 10 itself, and not on a partial system comprising only the electric machine 10. Furthermore, the calibration is performed for a particular operating point which is representative of operating conditions of the electric machine 10 during its use. Thus, the estimation model once calibrated allows an accurate estimation of the torque provided by the electric machine 10 during its subsequent operation, based on a measurement of the input electric current of the machine.

The method for calibrating the torque estimation model makes it possible to reduce, or even cancel out, the inaccuracies related to the indirect measurement of the torque via an electric current measurement, particularly the uncertainty related to the measurement of the electric current itself and to the manufacturing tolerances of the electric machine 10. The torque provided by the electric machine 10 is therefore estimated with reduced uncertainty, which is particularly compatible with the use of the electric machine 10 for aeronautic propulsion. Specifically, the calibration of the torque estimation model makes it possible to satisfy the flight safety imperatives, due to the improved accuracy of the torque measurement, making it possible to make an input electric current of the machine and an output torque of the machine accurately correspond with one another. The torque provided by the electric machine 10 can thus be better regulated. This regulation allows a more accurate control of the electric machine 10, such that the torque provided by the electric machine 10 during different flight phases is maximized, while being sure not to exceed the maximum torque for which the mechanical transmission system was designed and thus not running the risk of damaging it.

### Calibrating Device

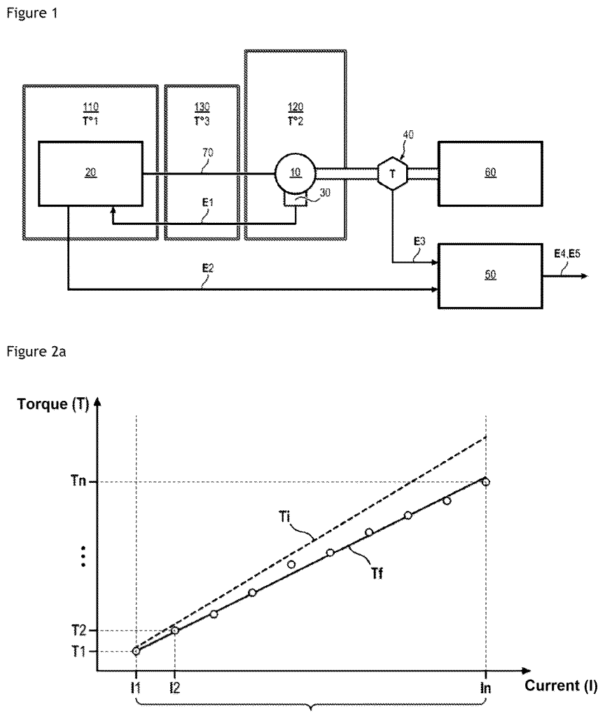

A calibrating device for estimating a torque provided by an electric machine 10, particularly by a permanent-magnet motor, is illustrated by way of non-limiting example in FIG. 1. The calibrating device comprises:
a device for measuring an electric current 30 suitable for measuring the electric current through the electric machine 10 for an operating point of the electric machine 10; advantageously, a device for measuring the electric current 30 already present in the electric machine 10 (and therefore able to be used in other processes relating to the electric machine 10) can be used, which makes it possible to avoid increasing the bulk or the mass of the electric machine 10;
an estimation model associating an output torque with an input electric current, such that the estimation model is suitable for estimating a torque provided by the electric machine for said operating point of the electric machine 10, based on the electric current measured by the measuring device 30;
a calibrating unit 50 comprising a torquemeter 40 suitable for measuring a reference torque provided by the electric machine 10 for the operating point of the electric machine 10; and suitable for comparing the estimated torque with the reference torque, the control unit 50 being moreover suitable for adjusting the estimation model according to said comparison, so as to reduce, or even cancel out, a difference between the estimated torque and the reference torque; and
a test bench 60 suitable for receiving the electric machine 10 for the calibration of the torque estimation model.

The torquemeter 40 can in particular be incorporated into the test bench 60. Whatever the circumstances, it is not necessary to incorporate the torque meter into the electric machine 10 itself, the torque meter 40 incorporated into the test bench 60 on the ground being enough to calibrate the model for estimating the torque provided by the electric machine 10.

The device for measuring the electric current 30 corresponds to the current sensor provided for the application. This can in practice be a Hall effect sensor, a shunt, a magneto-resistive sensor, or a fluxgate sensor. The type of device for measuring the electric current 30 is chosen according to different criteria, such as: the accuracy of the desired measurement, the space available for integration; the cost of the device for measuring the electric current 30. For example, it has been observed that a Hall effect sensor has a smaller bulk and a lower cost, but a more limited accuracy, than a fluxgate. One subject of the application is to allow the use of a current measurement sensor of lesser accuracy and cost, such as a Hall effect sensor, via a method and device for calibrating the torque estimation model based on this current measurement.

In practice, the device for measuring the electric current 30 can be located at the electric machine 10, or at the control system 20. The measured electric current corresponds to the electric current flowing in one phase of the electric machine 10, at the operating point.

The calibrating device is suitable for implementing the method described above, and therefore offers the same advantages of accuracy of calibration with no increase in the cost, mass or bulk of the system as the method described above.

The control system 20 of the electric machine 10 is suitable for commanding a rotation speed and a supply voltage of the electric machine 10. The control system 20 of the electric machine 10 in practice comprises control electronics and power electronics of the electric machine 10.

The power electronics comprise means for controlling the electric current flowing through the electric machine 10 which are suitable for the type of electric machine 10, such as a power converter, for example an inverter or a rectifier. The control electronics make it possible to control the power electronics.

The method described above makes it possible to perform the calibration on the whole system comprising the full electronic/electric power transmission system, from the control system 20 to the electric motor 10—including the power harness where applicable. Consequently, the uncertainties on the whole system are reduced, and not only the uncertainties on the electric machine 10 or the control system 20 of the electric machine 10 only.

The method may further comprise a step E6 of recording the adjusted estimation model in a memory of the control system 20.

The steps E1 to E4 can be repeated for several different operating points of the electric machine 10. Each operating point can be defined by one or more parameters of the electric machine, particularly comprising a temperature, a rotation speed, and a supply voltage of the electric machine. In other words, each operating point is defined by a given value or a combination (n-uplet) of values of operating parameters of the electric machine.

In more detail, for each operating point of the electric machine 10, the calibrating method comprises the following steps:
an input electric current of the electric machine 10 on the test bench 60 is measured in the step E1, a torque provided by the electric machine 10 is estimated in the step E2, a reference torque is measured by the torquemeter of the test bench 60 in the step E3, and the estimated torque is compared with the reference torque in the step E4. In particular, different operating points of the electric machine 10 may correspond to different electric currents in the electric machine 10. Consequently, the repetition of the steps E1 to E4 for different operating points makes it possible to estimate different torques, each corresponding to the different measured electric currents. Thus, the calibration is more accurate, and takes into account different operating conditions of the electric machine 10. The more numerous the operating points, the more accurate the calibration of the torque estimation model and the greater the improvement in the robustness of the torque estimation model.

The method for calibrating the model for estimating the torque provided by the electric machine 10 can be performed after receipt of the electric machine 10, and before the electric machine 10 is integrated into the propulsion system (aircraft) to which it must provide energy. In other words, the calibration of the estimation model is done on the ground, using the calibration unit 50 (on the test bench 60). This calibration of the torque estimation model is what makes it possible to have access, in flight, to an accurate estimate of the torque provided by the electric machine 10 on the basis of the input parameters of the estimator: particularly current, or supply voltage and/or temperature as will be explained further on, guaranteeing an optimal torque for each flight phase, in terms of propulsive efficiency and in terms of flight safety.

If, in the application (aircraft) in question, a power harness 70, i.e. a set of electric cables able to convey power signals between the control system 20, which is remote, and the electric machine 10 itself, provision is made for the calibrating device and method to incorporate such a power harness 70 in order to take into account the entire assembly formed by the full electronics/electrical power transmission system (from the control system 20 to the electric motor 10).

### Estimating the Torque (Step E2)

The estimating of the torque provided by the machine is done in the step E2 based on the electric current measured in the step E1 and on an estimation model associating an output torque with an input electric current by the calibrating unit 50.

An overall electric current range [I1, In] comprises the set of electric currents able to be applied at the input of the electric machine 10 in operation, i.e. during the different flight phases of the aircraft; it is therefore the set of electric currents measured during the step E1.

The calibration of the estimation model is preferably done over the whole global electric current range [I1, In], to obtain the best accuracy over the entire operating range of the machine (all the flight phases). The adjustment of the estimation model performed in the step E5 over the global electric current range [I1, In], makes it possible to minimize a difference between the set of estimated torques and the set of reference torques.

In a variant, the calibration of the estimation model can be done over a given electric current range [Ik, In], which is a reduced range and contained in the global electric current range [I1, In]. This allows for a particularly accurate calibration over this reduced range, since it is specifically optimized for this reduced range. Such a given electric current range [Ik, In], reduced by comparison with the global electric current range [I1, . . . , In], will typically comprise a selection of the electric currents measured in the step E1. The adjustment of the estimation model performed in the step E5 will then be applicable to the given electric current range [Ik, In], i.e. this step E5 takes into account the torques estimated based on the measured electric currents which are contained in this range; and does not take into account the torques estimated based on measured electric currents lying outside the given electric current range [Ik, In]. One thus obtains a particularly accurate calibration within the given electric current range [Ik, In]; but a much less accurate calibration outside this range [Ik, In].

The given electric current range [Ik, In] may correspond to a preferred operating range of the electric machine 10, or to a critical operating current range of the electric machine 10, in which the calibration must be particularly accurate. For example, in the field of aeronautical propulsion, the need for accuracy is particularly present near the maximum torque, so near the maximum electric current liable to be applied to the electric machine 10 in operation. Specifically, the dimensioning of the power transmission and the maximum power corresponds to a torque range located close to the maximum torque. Thus, the given electric current range [Ik, In] may correspond to an electric current range of between 90 and 100% of the maximum current value for the electric machine 10 under consideration, which corresponds to a torque range between 80 and 100% of the maximum torque value defined for the propulsion system under consideration.

The described calibrating method and device thus make it possible to calibrate an estimation model defined for an electric motor and a given propulsion system.

### Calibrating the Estimation Model

Several models of use may be used.

### Estimation Model Based on an Affine Function

The estimation model to be calibrated can, in a first example, be an affine function, i.e. a law which is a linear function of the measured electric current, and which relates the output torque to the input electric current. Such an affine function is defined by two parameters, a y-intercept and a gradient.

The calibrating method and device of such an affine function make it possible to adjust the parameters of the affine function.

For this purpose, initial values of these parameters, y-intercept and gradient, define an initial affine function stored in a memory of the calibration unit 50 during the step E6, and the calibrating method makes it possible to obtain a final affine function, based on the reference torque measurements for different input current measurements corresponding to different operating points of the machine.

The initial affine function Tini of the estimation model to be calibrated is written Tini. The initial affine function Tini is defined by an initial y-intercept Bini and an initial gradient Ktini, and provides a torque value Tini(x) based on a measured input current by application of the equation

$$Tini ( x ) = Ktini ⋆ lini + Bi . \qquad EQ 1$$

The adjustment of the estimation model performed in the step E5 comprises an adjustment of the initial gradient Ktini and/or of the initial y-intercept Bini of the initial affine function Tini. More specifically, the values of the parameters of and/or—intercept of the initial affine function Tini can be recalibrated by comparing the estimated measured reference torques and, for different operating points of the machine, such that a total distance from the estimated torques to the corresponding measured reference torques T1, . . . , Tn is minimized, or even cancelled out. One obtains a final affine function Tfin obtained by calibration of the estimation model, defines by the new parameters Ktfin and/or Bfin, such that one obtains a more accurate estimated torque value, written T*, for the electric current measurement Ii (for i an integer ranging from 1 (or k in the case of a reduced range) to n, and n being the number of operating points used. This value T* is given by: T*=Ktfin*Ii+Bfin.

The final affine function Tfin can be in practice obtained by performing a linear regression over the set of reference torques measured in the step E3, or on a selection of reference torques of this set, corresponding to a range of interest as explained above.

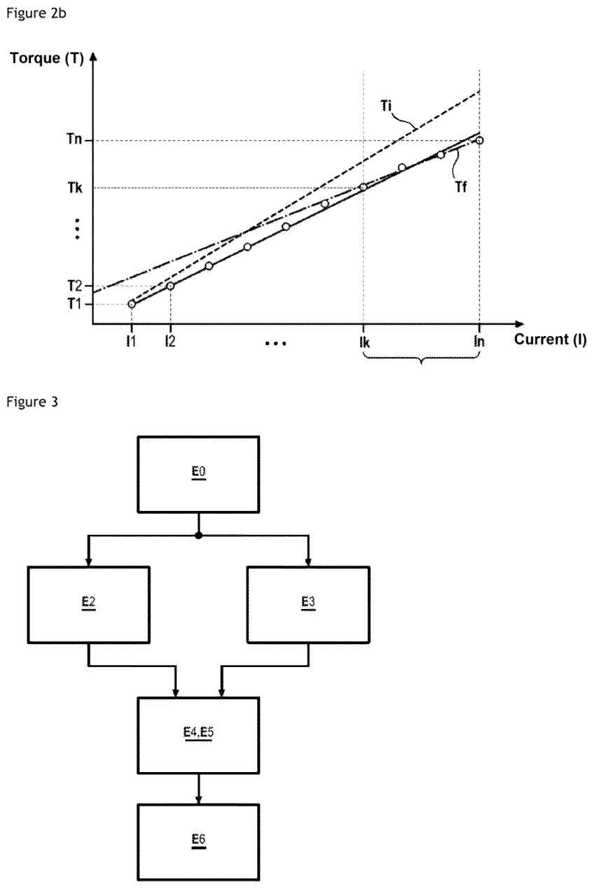

FIG. 2a illustrates by way of non-limiting example an estimation model which is adjusted in the step E5 such as to minimize the distance between the torques estimated in the step E2 and the reference torques T1, . . . , Tn measured in the step E3, over the global electric current range [I1, In]. Starting from the set of the different torques estimated by the initial affine function Tini, the final affine function Tfin is obtained by performing a linear regression over the set of corresponding measured reference torques T1, . . . . Tn. The y-intercept and/or the gradient of the torque estimation affine function are thus adjusted such that the final affine function Tfin corresponds to the linear regression over the set of measured reference torques T1, . . . . Tn over the global electric current range [I1, In] under consideration.

FIG. 2b illustrates by way of non-limiting example an estimation model which is adjusted in the step E5 so as to minimize the distance between a selection of estimated torques estimated in the step E2 over the given electric current range [Ik, In] corresponding to a range of interest, and a corresponding selection of the reference torques Tk, . . . , Tn measured in the step E3 over the given electric current range [Ik, In]. The final affine function Tfin is obtained by performing a linear regression over the selection of the measured reference torques Tk, . . . , Tn for the given electric current range [Ik, In]. The initial y-intercept Bi and/or the initial gradient Ktini of the torque estimation affine function are thus adjusted such that the final affine function Tfin corresponds to the linear regression over the selection of measured reference torques Tk, . . . . Tn for the electric currents situated in the given electric current range [Ik, In] under consideration. Thus, the calibration of the torque estimation model is particularly accurate over the given electric current range [Ik, In] of interest.

### Estimation Model Based on a Polynomial Function

In another example, the estimation model is based on a polynomial function of degree strictly greater than 1, for example a quadratic function, or a cubic function. The estimation model is suitable for estimating the output torque, as a function of the input electric current and as a function of coefficients associated with each degree of the polynomial function. The estimation model therefore comprises parameters corresponding to the coefficients associated with each degree of the polynomial function. These parameters are then stored in the memory of the control system 20 of the electric machine 10 during the step E6.

Such a polynomial function of degree strictly greater than 1 makes it possible to take into account the non-linearities in the estimate of the torque based on the electric current, for example when the torque constant of the electric machine 10 depends on the electric current. Specifically, one generally observes a lowering of the torque constant when the electric machine arrives at the magnetic saturation “bend”, close to the maximum current. The adjustment in the step E5 of the parameters of the polynomial function of degree strictly greater than 1 can be performed over the global electric current range [I1, In], or over a given electric current range [Ik, In], more restricted, and more specifically of interest in a similar way to that described above concerning the affine function.

### Estimation Model Based on any Other Function Relating the Measured Electric Current to the Estimated Torque

More generally, the estimation model comprises any function making it possible to estimate a torque provided by the electric machine 10 based on a measurement of the electric current through the electric machine 10. The estimation model comprises the parameter or parameters which define the function relating the measured electric current to the estimated torque. These parameters can be stored in the memory of the control system 20 during the step E6, and adjusted in a similar way to that shown and described above.

### Estimation Model Based on a Lookup Table

In yet another example, the estimation model comprises a lookup table associating a corresponding estimated output torque with each of a plurality of input electric currents. The lookup table of the estimation model thus comprises a plurality of input electric currents, and a plurality of corresponding estimated output torques. The adjustment of the estimation model performed in the step E5 thus comprises an adjustment of one or more input electric currents and/or output torques associated with the lookup table. In other words, one or more output torque values of the lookup table are recalibrated during the step E5 as a function of the comparison between the estimated torque and the reference torque made in the step E4, such as to reduce or even cancel out a difference between the estimated torque and the reference torque. Thus, when the current measurements recorded during the calibration test exactly match the initial input current values, only the torque values are updated; on the other hand, in the opposite case, both the input current and associated torque values are updated so that the table matches the values recorded during the calibration test. The use of a lookup table therefore means that it is not necessary to compare the torque estimated by the initial table and the torque actually measured. It is the fact of entering the measured torque values in the table that means that the error between the estimated torque obtained with the final table and the actual (measured) torque is minimized. The error is therefore of necessity zero for operating points exactly matching the input values of the table (currents). Between these points, the error depends on the interpolation function used, on the distance between the points and on the non-linearity of the actual torque over the interval between the points of the table.

The use of a lookup table allows an accurate calibration of the estimate of the torque provided by the electric machine 10, particularly when the relationship between the estimated torque and the measured electric current cannot be easily approximated by a mathematical function. The accuracy of the calibration thus also depends on the number of points of the lookup table (corresponding to a measured current value and torque value).

The larger the number of measured input electric current values associated with output estimated torques for a given electric current range contained in the lookup table, the more accurate the calibration.

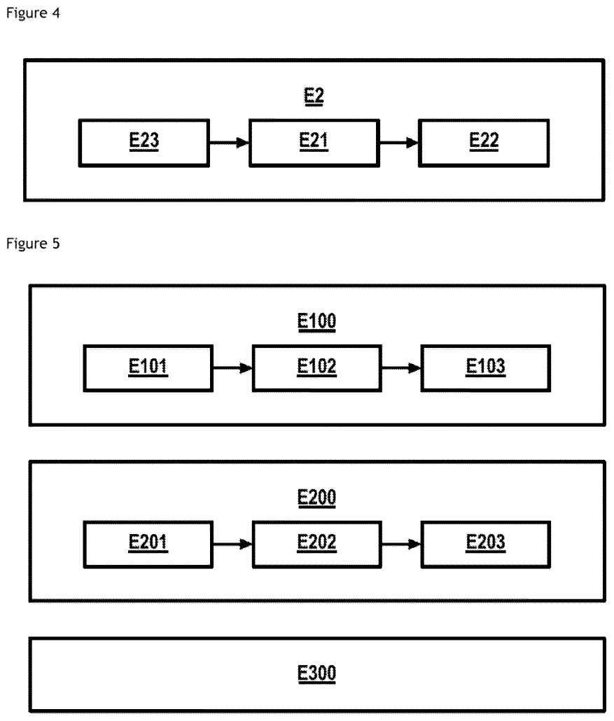

Optionally, as illustrated by way of non-limiting example in FIG. 4, the estimating of the torque in the step E2 may comprise a sub-step E21 of comparing the electric current measured in the step E1 with one or more electric currents from among the plurality of input electric currents, and a sub-step E22 of interpolation to deduce therefrom the estimated torque provided by the electric machine 10.

For example, the interpolation of the sub-step E22 can be a linear interpolation. In particular, if the electric current measured in the step E1 is situated between a first and a second, adjacent input electric current of the lookup table, while the torque provided by the electric machine 10 can be estimated by linear interpolation performed between the first output torque and the second, adjacent output torque, respectively associated with the first input electric current and with the second input electric current. Thus, a relative distance between the measured electric current and the first input electric current, or respectively between the measured electric current and the second input electric current, is equal to a relative distance between the estimated torque and the first output torque, or respectively between the estimated torque and the second output torque.

Taking into Account of Other Variables

The lookup table can be a one-dimensional lookup table, said dimension corresponding to the electric current measured in the electric machine 10. Such a one-dimensional lookup table makes it possible to compensate for the sensitivity of the magnetic flux to the electric current, to increase the accuracy of the estimate of the torque provided by the electric machine 10. Specifically, a field saturation bend phenomenon incurs a smaller variation in the torque for strong electric currents than for weaker electric currents.

In a variant, the lookup table can be a multi-dimensional lookup table. The lookup table may comprise a first dimension corresponding to the electric current measured in the electric machine 10, and one or more additional dimensions corresponding:
to a temperature, which may be a temperature to which the electric machine 10 is exposed, and/or a temperature to which the control system 20 is exposed; and/or
to a supply voltage and a rotation speed of the electric machine 10.

The plurality of input electric currents associated with the plurality of output torques is then determined for each temperature and/or supply voltage and rotation speed of the lookup table. In other words, the estimation model comprises one or more sets of lookup tables, a first set of lookup tables being associated with a temperature and/or a second set of lookup tables being associated with a supply voltage and a rotation speed. The estimating of the torque in the step E2 then comprises a sub-step E23 of selecting a lookup table associated with a temperature and/or with a supply voltage and rotation speed of the electric machine 10 at the operating point of the electric machine for which the electric current is measured in the step E1.

Such a lookup table with more than one dimension makes it possible to compensate for the sensitivity of the determination of the torque provided by the electric machine 10 to different environmental factors, such as the variability of the torque constant of the electric machine with temperature (the influence of the temperature on the magnetic field produced by the magnets and on the reluctance of the metal stator sheets) or else the variability of the measurement error of the current sensors with temperature, which makes it possible to further improve the accuracy of the calibration.

The temperature to which the electric machine 10 and/or the control system 20 is exposed can for example be a temperature measured as near as possible to the electronic components of the electric machine 10 and/or the control system, or in the nearby external environment of the electric machine 10 and/or of the control system.

A lookup table comprising an additional dimension corresponding to the temperature to which the electric machine 10 and/or the control system 20 is exposed thus makes it possible to compensate for the sensitivity of the measurement of the electric current through the electric machine 10 to temperature and/or the influence of the temperature on the torque provided by the electric machine 10 for a given electric current, and therefore to further increase the accuracy of the calibration of the torque estimation model.

For example, the lookup table can be a two-dimensional table, the second dimension corresponding to the temperature to which the electric machine 10 and/or the control system 20 is exposed. In other words, the estimation model comprises a set of lookup tables, each lookup table being associated with a temperature from among a set of operating temperatures of the electric machine 10. The estimating of the torque in the step E2 comprises a step E23 of selecting a lookup table associated with a temperature of the electric machine 10 at the operating point.

The selecting step E23 may comprise the application of a time-domain filter representative of a dynamic model of the variation in temperature. The time-domain filter is configured to model a temperature deviation between a temperature measurement point, typically stator winding heads of the electric machine 10) and a point of interest for this temperature parameter, typically at the magnets located on the rotor of the electric machine 10. Thus, the selected lookup table is the one that best matches the temperature at the point of interest, since it affects the torque constant Kt of the electric motor, which makes it possible to further improve the accuracy of the calibration of the torque estimation model. The time-domain filter therefore models the inertia in the variation of the temperature between the measurement point and the point of interest. The time-domain filter can be calibrated by measurements on the test bench 60, by means of a specific instrumentation making it possible to accurately measure the temperature at the temperature measurement point that will be available (measurable) in operational conditions (during the flight phases) and at the point of interest.

A lookup table comprising an additional dimension which corresponds to a supply voltage and a rotation speed of the electric machine 10 is particularly useful in the case of an electric machine 10 of permanent-magnet motor type, liable to be exposed in operation to strong variations in supply voltage and/or rotation speed. Specifically, in this case, one generally uses a so-called defluxing command which makes it possible to adapt the operation of the electric machine 10 to different supply voltages and rotation speeds of the electric machine 10. The torque provided by the electric machine 10 then depends on the combination of the level of supply voltage and of the rotation speed of the electric machine 10. The lookup table can for example be a single lookup table, the additional dimension of which corresponds to the ratio of the supply voltage to the rotation speed, or in a variant be a lookup table comprising a first additional dimension corresponding to the supply voltage and a second additional dimension corresponding to the rotation speed.

The lookup table or tables of the estimation model can be stored in the memory of the control system 20 of the electric machine during the step E6.

The lookup table or tables of the estimation model are adjusted in the step E5 so as to minimize the distance between the torques estimated in the step E2 and the reference torques T1, . . . , Tn measured in the step E3, over the global electric current range [I1, In], or over the given electric current range [Ik, . . . , In]. In other words, the modification in the step E5 of the output torques and where applicable the associated input electric currents can be performed over the global electric current range [I1, In], or over the given electric current range [Ik, In], in a similar way to that described above concerning the estimation model comprising an affine function.

It will be understood that the taking into account of operating parameters of the electric machine, and in particular the temperature to which the electric machine 10 and/or the control system 20 is exposed, and/or the supply voltage and the rotation speed of the electric machine 10, in addition to the measurement of the electric current measured to provide an estimated output torque value of the electric machine, is applicable in a similar way to situations in which the relationship between the current and the torque can be modeled by a mathematical function, particularly affine or polynomial, or otherwise, as long as corresponding measurements are available. Thus everything that has been said about the measurement and taking into account of the temperature, or the measurement and taking into account of the supply voltage and of the rotation speed as regards defluxing, is applicable in a similar way to these estimation functions.

More specifically, the estimation model then comprises a function, for example affine, polynomial of degree strictly greater than 1, or of any other type that may be envisioned, comprising one or more independent variables associating an estimate of a corresponding output torque with a measured input electric current, for different values or ranges of values of these additional parameters. For example, a first variable can be associated with a temperature and/or with a supply voltage and a rotation speed. The estimating of the torque in the step E2 then comprises a sub-step E23 of determining an independent variable associated with a temperature and/or an independent variable associated with a supply voltage and rotation speed of the electric machine 10 at the operating point of the electric machine 10 for which the electric current is measured in the step E1 and/or a variable associated with the ratio of the supply voltage to the rotation speed. The estimation model thus makes it possible to compensate for the sensitivity of the measurement of the electric current through the electric machine 10 to the temperature and/or to the supply voltage and rotation speed, and/or to compensate for the influence of the temperature and/or of the supply voltage and rotation speed on the torque provided by the electric machine 10 for a given electric current, and thus to further increase the accuracy of the calibration of the torque estimation model.

### Calibrating Method Sequence

### First Embodiment—Simultaneous Calibration of the Electronic Control System 20 and of the Electric Machine 10

The method comprises a prior step of installing the electric machine 10 on a test bench 60.

The method comprises a step E0 of controlling the calibrating device, in particular of controlling the electric machine 10 by the control system 20, so as to reach the operating point.

Each operating point of the electric machine 10 may be defined in practice by a rotation speed of the electric machine 10 and/or by a level of power provided by the electric machine 10 and/or by a temperature to which the electric machine 10 is exposed and/or by a temperature to which the control system 20 of the electric machine 10 is exposed and/or by an electric current through the electric machine 10. Specifically, the torque estimation based on the electric current measurement, as well as the means for measuring the electric current, may be sensitive to the conditions of use, in particular to the temperature. Thus, an operating point which depends in particular on the temperature makes it possible to perform a more accurate calibration of the torque estimate.

To allow the establishment of the calibration of the estimation functions or the establishment of the lookup tables and take into account the influence of the temperature, the calibrating device comprises at least a first thermal chamber in which at least the electric motor 10 is placed, making it possible to take the measurements of reference torque at the output of the electric motor at the different operating points and for different temperatures.

The calibrating device preferably comprises at least two, or even three, thermal chambers, making it possible to replicate the operating temperature conditions as well as possible, for the different types of installation/design of the electric machine 10 and its control electronics, which may be in proximity to one another and at substantially the same temperature, or on the contrary remote and connected by a power harness.

It is then possible to place each of the functional units from among the electric motor 10, the control system 20 and the power harness 70 under temperature conditions representative of the actual operating environment:
a first chamber 110 suitable for replicating first external conditions, the first chamber 110 being suitable for receiving the electric machine 10 during the calibration;
a second chamber 120 suitable for replicating second external conditions, the second chamber 120 being suitable for receiving the control system 20 of the electric machine 10 during the calibration; and
optionally, a third chamber 130 suitable for replicating third external conditions, the third chamber 130 being suitable for receiving the power harness 70 when the control system 20 is remote from the electric machine 10, the power harness 70 connecting the electric machine 10 to the control system 20. This is because the temperature of the cables of the power harness 70—which influences the electrical resistance of said cables—also influences the measured electric current. By making provision for a thermal chamber 130 specific to the power harness 70 the influence, to the extent of the electric current, of temperature on the resistance of the cables of the power harness 70 is better taken into account.

The first external conditions may comprise a first temperature T°1. The second external conditions may comprise a second temperature T°2, which can be equal to or different from the first temperature T°1. Thus, the conditions replicated in the first chamber 110 may be identical to or different from those replicated in the second chamber 120. These two chambers 110, 120 therefore make it possible to model either the situation in which the electric machine 10 and the control system 20 are exposed to the same external conditions, or the situation in which the electric machine 10 and the control system 20 are exposed to different external conditions.

The first external conditions replicated by the first chamber 110 may substantially correspond to the conditions liable to be encountered by the electric machine 10 during its operation. The second external conditions replicated by the second chamber 120 may substantially correspond to the conditions liable to be encountered by the control system 20 of the electric machine 10 during its operation. Thus, the electric machine 10 and the control system 20 of the electric machine 10 can each be exposed to identical or different external conditions, representative of their respective operating conditions. The third external conditions may comprise a third temperature T°3, which can be equal to or different from the first temperature T°1 and/or the second temperature T°2.

When the electric machine 10 and the control system 20 are liable to be exposed to substantially identical external conditions during their operation, the electric machine 10 and the control system 20 can both be placed in the first chamber 110, or be respectively placed in the first chamber 110 and in the second chamber 120, the first and second external conditions then being identical. Optionally, when the power harness 70 is also liable to be subjected to substantially identical external conditions to those of the electric machine 10 and of the control system 20, the power harness 70 may be placed in the first chamber 110, or respectively in the second chamber 120, or may be located in the third chamber 130, the first, second and third external conditions then being identical.

When the control system 20 is embedded in the electric machine 10, these two functional blocks are in proximity to one another and can be considered as being exposed to uniform temperatures.

They could therefore be placed in one and the same chamber 110, or else in two chambers 110, 120 which are separate but configured to replicate external conditions, in particular temperature conditions, that are substantially identical, over the range of variation of these conditions. The temperatures to which the electric machine 10 and the control system 20 are liable to be exposed may vary over large amplitudes, for example as a function of:
the ambient atmospheric temperature, which in the aeronautical field, can vary from −50° C. to +70° C.,
the temperature in the immediate environment of the electric machine 10, which can be affected by the operation of other items of equipment, for example the temperature in an engine compartment such as an airplane nacelle or an engine compartment of a helicopter is heavily dependent on the operation of the gas turbine,
the temperature of the electrical parts and electronic components of the electric machine 10 and of the control system 20, which greatly varies with the operating power of the electric machine 10 itself due to self-heating caused by the flow of electric current.

When the control system 20 of the electric machine 10 is remote from the electric machine 10, a power harness 70 connects these two functional blocks. The electric machine 10, the control system 20 and the power harness 70 are then generally exposed to substantially different temperature conditions.

In particular, the electric machine 10 and its electromagnetic parts may be exposed to extreme temperatures, for example greater than 100° C., particularly when the electric machine 10 is located in an engine compartment such as an airplane nacelle or an engine compartment of a helicopter. On the other hand, the control system 20 can be exposed to lower temperatures when the control system 20 is remote to be placed in a more protected environment in which the temperature is kept in a lower, or even very low, range, for example less than 20° C. or less than −40° C. An operating point of the electric machine 10 can for example be reached for a given rotation speed and/or supply voltage of the electric machine 10 placed in the first chamber 110 replicating a temperature greater than 100° C., the control system 20 being placed in the second chamber 120 replicating a temperature less than −40° C., a harness 70 being where applicable placed in one from among the first and second chamber 110, 120 or in a dedicated third chamber 130, under the conditions liable to be encountered by the harness 70.

Such a calibrating method using one or more chambers 110, 120, 130 comprising the electric machine 10 and/or the control system 20 and/or the power harness 70, makes it possible to perform a global calibration of the assembly comprising the electric machine 10, the control system 20 of the electric machine 10, and where applicable the power harness 70 and makes it possible to erase as much as possible the uncertainties related to the set of environmental and topological parameters of the system, which allows a more reliable, accurate and easily implemented calibration. By characterizing the control system 20 and the electric machine 10 in a global way, the calibrating method is moreover simple to perform while guaranteeing the obtainment of a torque estimation model that is accurate and robust to the conditions of use.

### Second Embodiment—Separate Calibration of the Electronic Control System 20 and of the Electric Machine 10

In a second exemplary embodiment, as illustrated by way of non-limiting example in FIG. 5, the electronic control system 20 and the electric machine are calibrated separately. This specifically makes it possible to simplify the implementation of the invention in the event of maintenance, particularly when the control system 20 is remote and has to be replaced in the event of a malfunction. In particular, provision is made here for calibrating the control system 20 and the electric machine 10 independently from one another. More precisely, in this embodiment, the current measurement of the control system 20 is characterized using a master current measurement system in order to obtain a shaping table of the current measurement as a function of the current actually commanded by the power electronics of the control system 20 and where applicable of the operating conditions which can affect the accuracy of the current measurement of the control system (e.g. environmental temperature, supply voltage etc.) (step E200). This shaping table is therefore specific to each control system 20. An electric motor 10 can therefore be associated with any control system 20 simply by loading the shaping table obtained for this control system 20. Similarly, the torque constant of the electric machine 10 is characterized as a function of the applied current and measured using the master current measurement system and compared with the value of the torque measured using a test tooling (torquemeter of the test bench) (step E100). One therefore obtains a shaping table of the torque as a function of the current flowing through the motor and where applicable of the operating conditions. This torque shaping table is therefore specific to each electric motor 10. A control system can thus be associated with any electric motor 10 simply by loading the torque shaping table obtained for this electric motor 10.

Thus, by using a reference system for the determination of the estimation model, it is then possible to obtain a model, valid for a given electric motor 10, but adaptable by simple mapping to any electronic control system, without requiring any recalibrating of the electronic control system when this must be changed.

For this purpose, the calibrating method comprises:
a step E100 of calibrating the electric machine 10, comprising a sub-step E101 of measuring the no-load electromotive force of the electric machine 10 and a sub-step E102 of measuring a rotation speed of the electric machine 10, for an operating point of the electric machine 10, and a sub-step E103 of determining an electric machine model associating with the electromotive force a rotation speed of the electric machine 10, based on the measured electromotive force and on the measured rotation speed;
a step E200 of calibrating the control system 20, comprising a sub-step E201 of measuring an electric current of the power electronics of the control system 20 on a static load test bench equipped with a master current sensor serving as reference (and where applicable, a harness 70); a sub-step E202 of computing a measurement error on the quadratic current of the control system 20 with respect to the master current sensor serving as reference. These measurements can be taken for different current setpoints in order to cover a range of current of interest, optionally for different conditions of use which can affect the accuracy of the measurement of the current of the control system (e.g. environment temperature, supply voltage etc.) Advantageously, the measurement of the reference current on a static load test bench makes it possible to obtain robust and very accurate measurements; and a sub-step E203 of creating a shaping model associating the reference current measurement as a function of the current actually commanded by the power electronics, and optionally the operating conditions (temperature, rotation speed etc.), in order to determine correction parameters of the electric current commanded by the power electronics of the control system 20 based on the current measured by the master current sensor serving as reference; and
a step E300 of storing in the control unit 50 of the electric machine model and of the shaping model in a memory of the command system 20.

The calibration of the electric machine 10 in the step E100, or respectively of the control system 20 in the step E200, thus remains valid when the control system 20, or respectively the electric machine 10, is changed, for example in the event of a malfunction of the control system 20, or of the electric machine 10 respectively. In particular, if the control system 20 is remote from the electric machine 10, the control system 20 can often require changing during servicing of the system, and changing independently of the electric machine 10. The command system can thus be associated with any electric machine, conditional on the loading of the shaping table of the torque estimator associated with the driven machine

The estimation model is defined taking into account the electric machine model and the control system model independently. The estimation model may correspond to the sum of the electric machine model and of the control system model. The control unit 50 can thus be associated with any electric machine 10 and/or with any control system 20, conditional on the changing of the electric machine model or of the control system model in the event of the electric machine 10 or the control system 20 replacement.

The measurement of the no-load electromotive force is done in sub-step E101 by driving the electric machine 10 empty, i.e. without any load, in order to gather the datum of the no-load electromotive force, where applicable as a function of the temperature of the electric machine 10. Several measurements of electromotive force at different operating temperatures of the electric machine 10 can be made, in order to obtain a table of electromotive forces as a function of temperature.

The electromotive force (FEM) manifests as the voltage generated by the electric machine when the electric machine 10 is rotationally driven at a certain speed. The relationship between the rotation speed of the electric machine 10 and the electromotive force is identical to the relationship between the electric current and the torque.

The calibration of the electric machine 10 is therefore performed in the step E100 by identifying the relationship between the rotation speed of the electric machine 10 and the electromotive force, which makes it possible to accurately deduce therefrom the relationship between the measured electric current and the torque provided by the electric machine 10, these relationships being identical. In other words, based on the estimation of the relationship between current and torque, via the measurement of the electromotive force, and on the reference current measurement by the master current sensor serving as reference on the static load test bench, it is possible to construct the torque estimation model (table or function). The electrical machine model determined in the sub-step E103 comprises one or more parameters associating a torque provided by the electric machine 10 with the measured electric current, where applicable also as a function of other operating parameters, such as the temperature, a quadrature current, etc.

The sub-step E201 of measuring electric current through the electric machine 10 may comprise three electric current measurements Ia, Ib and Ic, which are the currents flowing through each phase of the electric machine 10. The reference electric current Iq can be computed, in a manner known per se, based on these three electric current measurements Iq=function (Ia, Ib, Ic), this function being a 3×3 matrix which depends on the position measurement of the rotor of the electric machine (Park transform). Thus, the electric current measurement is reconstituted by computation based on phase current measurements of the electric machine 10.

The control system model associates with the measured electric current the computed quadrature current and the electric current commanded by the control system 20: Imes=function (Iq, Iref).

The control system model created in the sub-step E203 can moreover associate with the measured electric current a temperature of the control system 20: Imes=function (Iq, Iref, T°2).

When the control system 20 (or where applicable the electric machine 10) is replaced, the old control system model is replaced by the new control system model (or electric machine model respectively), which is obtained by the calibration of the new control system 20 in the step E200 (or respectively of the new electric machine in the step E100).

The parameters of calibration of the electric machine model can be stored in a memory of the control system 20 intended for the electric machine 10. Thus, it is simple to program the control system 20 which must be paired with the electric machine 10, with the calibration parameters of the current measurement.

As an option, and for the calibration parameters of the electric machine 10 itself, in particular the torque coefficient Kt, provision is advantageously made for physically attaching a memory card to the electric machine 10, with an ad hoc interface between this card and the control system 20, to store these parameters.

Other embodiments may be envisioned and those skilled in the art can easily modify the embodiments or exemplary embodiments set out above or envision others, while remaining within the scope of this application.

1. A method for calibrating a model for estimating a torque provided by an electric machine, the method comprising the following steps:
E1: measuring an electric current through the electric machine for an operating point of the electric machine;
E2: estimating the torque provided by the electric machine for said operating point of the electric machine, based on the electric current measured and on an estimation model associating an output torque with an input electric current;
E3: measuring a reference torque provided by the electric machine for said operating point of the electric machine;
E4: comparing the estimated torque with the reference torque; and
E5: as a function of the comparison in step E4, adjusting the estimation model so as to reduce, or cancel out, a difference between the estimated torque and the reference torque.

2. The method as claimed in claim 1, further comprising a step E6 of storing the adjusted estimation model in a memory of a control system.

3. The method as claimed in claim 1, wherein the steps E1 to E4 are repeated for several different operating points of the electric machine.

4. The method as claimed in claim 1, wherein the estimation model comprises an affine function, and wherein adjusting the estimation model comprises adjusting a gradient and/or of a y-intercept of the affine function.

5. The method as claimed in claim 1, wherein the estimation model comprises a lookup table associating with each of a plurality of electric input currents a corresponding output torque, and wherein the estimating of the torque in the step E2 comprises a recalibration of at least one output torque value of the lookup table during the step E5 as a function of the comparison between the estimated torque and the reference torque made in the step E4, to reduce or cancel out the difference between the estimated torque and the reference torque.

6. The method as claimed in claim 5, wherein the estimation model comprises a set of lookup tables, each lookup table being associated with a temperature from among a set of operating temperatures of the electric machine, and
wherein the estimating of the torque in the step E2 comprises a sub-step of selecting a lookup table associated with a temperature of the electric machine at the operating point.

7. The method as claimed in claim 1, wherein the estimation model is adjusted so as to reduce, or cancel out, the difference between the estimated torque and the reference torque, over a predetermined electric current range, and/or for a predetermined operating temperature range.

8. The method as claimed in claim 1, comprising:
a step of calibrating the electric machine, comprising a sub-step of measuring a no-load electromotive force of the electric machine and a sub-step of measuring a rotation speed of the electric machine, for the operating point of the electric machine, and a sub-step of determining an electric machine model associating with the no-load electromotive force, the rotation speed of the electric machine, based on the measured no-load electromotive force and the measured rotation speed;
a step of calibrating a control system, comprising a sub-step of measuring an electric current through the control system on a static load test bench equipped with a master current sensor to obtain a reference current measurement, a sub-step of computing a measurement error on a quadratic current of the control system with respect to the reference current measurement, and a sub-step of creating a shaping model in order to correct a current measurement commanded by the control system based on the reference current measurement; and
a step of storing the electric machine model and the shaping model of the control system in a controller.

9. A calibrating device for estimating a torque provided by an electric machine, the calibrating device comprising:
a measuring device that measures an electric current suitable for measuring the electric current through the electric machine for an operating point of the electric machine;
an estimation model associating an output torque with an input electric current, such that the estimation model is configured to estimate the torque provided by the electric machine for said operating point of the electric machine, based on the measured electric current;
a torquemeter configured to measure a reference torque provided by the electric machine for said operating point of the electric machine; and
a controller configure to compare the estimated torque with the reference torque, and to adjust the estimation model as a function of said comparison, so as to reduce, or cancel out, a difference between the estimated torque and the reference torque.

10. The calibrating device as claimed in claim 9, further comprising:
a first chamber configured to replicate first external conditions, and to receive the electric machine during calibration by the calibrating device; and
a second chamber configured to replicate second external conditions, and to receive a control system of the electric machine-during the calibration.

11. The method as claimed in claim 1, wherein the electric machine comprises a permanent-magnet motor.

12. The calibrating device as claimed in claim 9, wherein the electric machine comprises a permanent-magnet motor.
